(19) United States
(12) Patent Application Publication
(10) Pub. No.: US 2020/0064406 A1
(43) Pub. Date: Feb. 27, 2020

(54) METHOD FOR DIAGNOSING A TECHNICAL SYSTEM

(71) Applicant: AVL LIST GMBH, Graz (AT)

(72) Inventors: Daniel Ritzberger, Wien (AT); Stefan Jakubek, Wien (AT)

(21) Appl. No.: 16/347,140

(22) PCT Filed: Nov. 2, 2017
(86) PCT No.: PCT/EP2017/078007

§ 371 Date: May 2, 2019

(30) Foreign Application Priority Data
Nov. 4, 2016 (AT) A51008/2016

(51) Int. Cl. G01R 31/367; H01M 8/04992; H01M 8/04664

(52) U.S. Cl. CPC G01R 31/367; H01M 8/04671; H01M 8/04992

(57) ABSTRACT

Aspects of the disclosure are directed to a technical system modelled as a Volterra series with Volterra kernel (Hₙ(ω₁ . . . , ωₙ)). In a fault-free state of the technical system a Volterra kernel (H_{n,nom}(ω₁, . . . , ωₙ)) of the nth order is determined for the fault-free state. For a defined fault state of the technical system a Volterra kernel (H_{n,fault}(ω₁, . . . , ωₙ)) of the nth order is determined for the fault state. An evaluation kernel (H_{n,diff}(ω₁ . . . , ωₙ)) of the nth order is determined as a function of the Volterra kernel (H_{n,nom}(ω₁, . . . , ωₙ)) of the nth order for the fault-free state and of the Volterra kernel (H_{n,fault}(ω₁, . . . , ωₙ) of the nth order for the fault state. The evaluation kernel (H_{n,diff}(ω₁ . . . , ωₙ)) of the nth order is evaluated to determine a frequency range in which the amplification of the evaluation kernel (H_{n,diff}(ω₁ . . . , ωₙ)) exceeds a predefined limit value and an excitation frequency (ωₘ) is selected from this range for an excitation signal (a(t)).

The present invention relates to a method for diagnosing a technical system which maps an input signal onto an output signal, wherein, during the operation of the technical system, the input signal is superimposed by an excitation signal with at least one excitation frequency, and for diagnosing, the input signal and/or the output signal is analyzed to detect a fault state of the technical system.

There are different known diagnostic methods for diagnosing a galvanic element, in particular a fuel cell. A good overview of known methods can be found in Jinfeng Wu, et al., “Diagnostic tools in PEM fuel cell research: Part I Electrochemical Techniques,” Int. Journal of Hydrogen Energy 33 (2008), pages 1735-1746. A very simple method is the measurement of the polarization curve in the form of a static relationship between current and voltage. In order to determine the polarization curve, the current is measured as a function of a changing voltage, or vice versa. Polarization curves provide information about the general behavior of galvanic elements at specific operating states. However, with the evaluation of a polarization curve, neither different, simultaneously occurring states nor dynamic processes can be analyzed. However, individual fault states can have the same effect on the polarization curve, and so in some circumstances, individual fault states are not distinguishable. In order to simplify or even make possible a fault distinction, dynamic effects can be taken into account. A significant disadvantage of this method, however, is that the analysis of the polarization curves is time-consuming and cannot be used during the operation of the galvanic element.

Another frequently used method is electrochemical impedance spectroscopy which allows for the detection of the dynamic behavior of the galvanic element. For this purpose, a small alternating current or a small alternating voltage of known amplitude and excitation frequency (also a plurality of excitation frequencies) is impressed onto the galvanic element and the response (in amplitude and phase) is measured and evaluated as a function of the excitation frequency. The evaluation is carried out by analyzing the fundamental wave or the fundamental waves at a plurality of excitation frequencies. Electrochemical impedance spectroscopy can also diagnose different influences on the current operating state, and the method can also be used during the real operation of the galvanic element.

Another known method, called total harmonic distortion analysis (THDA), builds on the electrochemical impedance spectroscopy and analyzes the ratio of the fundamental oscillation to its harmonic content. This method is described in EP 1 646 101 B1 or in Ramschak E., et al., “Detection of fuel cell critical status by stack voltage analysis,” Journal of Power Source 157 (2006), pages 837-840.

However, both electrochemical impedance spectroscopy and THDA are based on the fact that the excitation frequency is known in advance, with which a specific state of the galvanic element can be optimally excited in order to allow for a meaningful diagnosis. The “healthy”, i.e., fault-free, galvanic element provides a different response to an excitation signal than a galvanic element with a faulty state. The excitation signal, in particular the excitation frequency, is supposed to excite this fault state particularly well in order to be able to diagnose the faulty state. Essentially, this means that the amplitude of the response of the galvanic element to an excitation signal must be sufficiently high in order to be able to be detected by measurement and evaluated in a reliable manner. However, the problem is that a particular excitation frequency does not excite each fault state equally. It is thus necessary to excite specific fault states with different excitation frequencies. However, these optimal excitation frequencies for a particular galvanic element are not known in advance but, until now, have had to be empirically determined in an elaborate manner.

The use of a broad excitation frequency band does not solve this problem, or solves it only to a limited extent, because it results in frequency overlays and intermodulations mainly due to the nonlinear behavior of the galvanic element. As a result, it is possible that the measured response of the galvanic element to the excitation signal can no longer, or no longer unambiguously, be evaluated and assigned to a specific fault state. When using a plurality of excitation frequencies, they are thus supposed to be selected such that the individual excitation frequencies do not influence each other, which is not the case for an entire frequency band. From that it follows, that instead of a continuous frequency spectrum, inherently only discrete excitation frequencies are suitable for the excitation.

The above explanations can also be generally applied to technical systems, whose function is supposed to be diagnosed by evaluating the response of the technical system (output variable) to a specific excitation (input variable) with a specific excitation frequency. Galvanic elements or electrolyzers are taken particularly into consideration as a technical system. For example, a galvanic element is a battery, an accumulator, or a fuel cell. A fuel cell can be, for example, an alkaline fuel cell (AFC), a polymer electrolyte fuel cell (PEMFC), a direct methanol fuel cell (DMFC), a phosphoric acid fuel cell (PAFC), a molten carbonate fuel cell (MCFC), or a solid oxide fuel cell (SOFC). An electrolyzer can be, for example, a polymer electrolyte electrolyzer, a solid oxide electrolyzer, or an alkaline electrolyzer.

The present invention therefore addresses the problem of determining in a simpler manner an excitation frequency for a diagnostic method of a technical system on the basis of the excitation of the technical system with an excitation signal with the excitation frequency.

According to the invention, this problem is solved by modelling the technical system as a Volterra series with Volterra kernel, determining in the fault-free state of the technical system, a Volterra kernel of the n-th for the fault-free state, determining for a defined fault state of the technical system, a Volterra kernel of the n-th order for the fault state, forming an evaluation kernel of the n-th order from the Volterra kernel of the n-th order for the fault-free state and the Volterra kernel of the n-th order for the fault state and evaluating the evaluation kernel of the n-th order to determine a frequency range, in which the amplification of the evaluation kernel exceeds a predefined limit value, and selecting the excitation frequency for the excitation signal from this frequency range. This approach allows for a systematic, simple determination of the excitation frequencies of the technical system, which are optimal for a specific fault state.

Preferably, an excitation frequency for the excitation signal is selected, in which the amplification of the evaluation kernel of the n-th order assumes a maximum value. In this manner, the best possible excitation for the diagnosis can be expected. In addition, a maximum value search can also be easily automated to determine the excitation frequencies in a completely automated manner.

Since a direct estimate of the Volterra kernels from input/output data is generally not possible, it is preferred to use a parametric model, such as a nonlinear, polynomial NARMAX or NARX model, from which the Volterra kernels can be derived analytically. The parametric model is preferably estimated in the time domain from known data. From the parametric model, the Volterra kernels are preferably derived analytically using the harmonic probing algorithm.

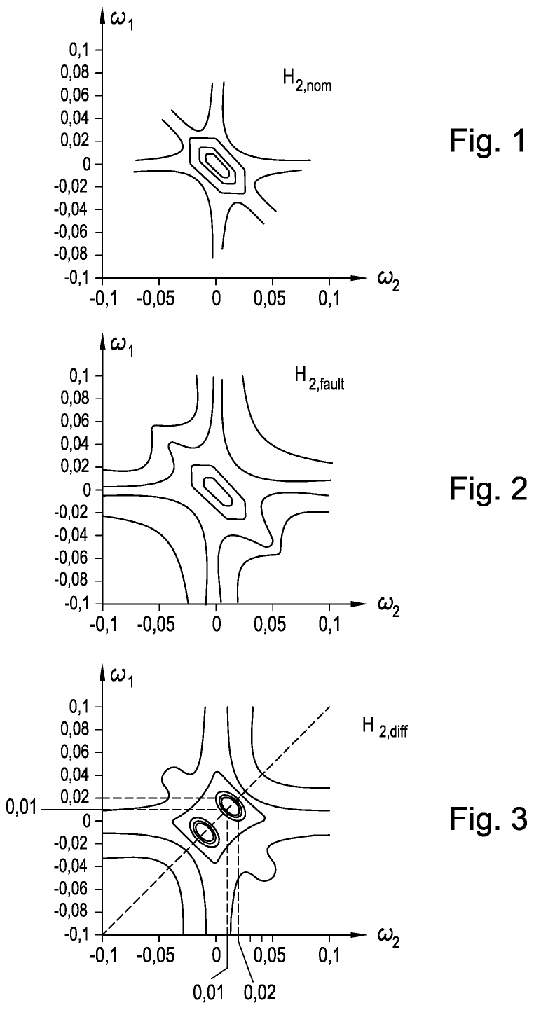

In the following, the present invention is described in greater detail with reference to FIGS. 1 to 6 which, by way of example, show schematic and non-limiting advantageous embodiments of the invention. In the drawings:

FIG. 1 shows a Volterra kernel of the 2nd order of the technical system in a fault-free state;

FIG. 2 shows a Volterra kernel of the 2nd order of the technical system in a faulty state;

FIG. 3 shows the resulting difference-kernel kernel of the 2nd order;

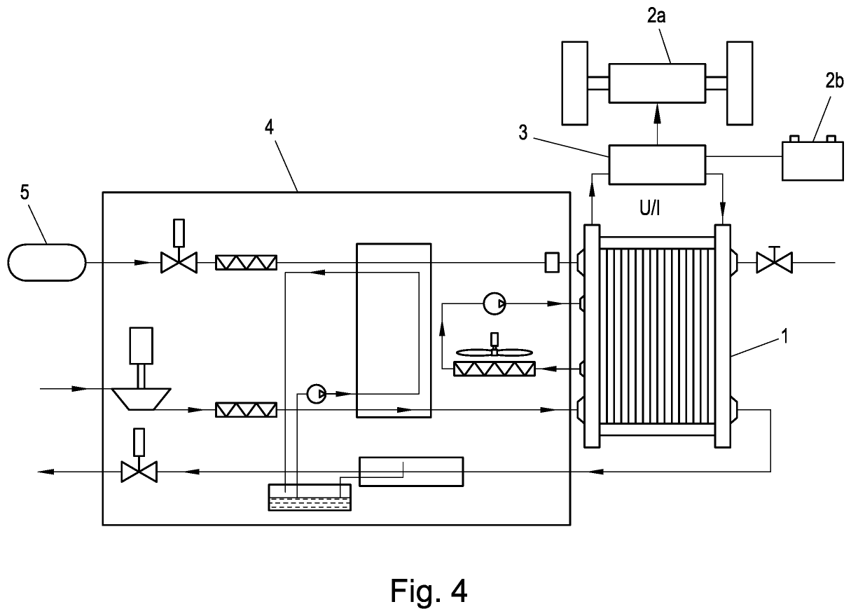

FIG. 4 shows a fuel cell as an example of a technical system to be diagnosed;

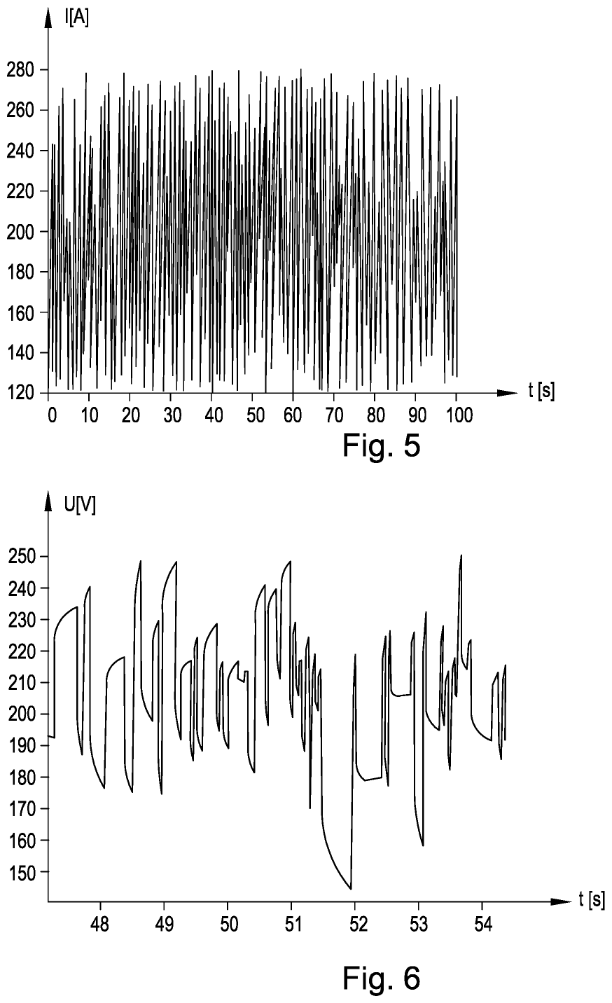

FIG. 5 shows an exemplary APRBS input signal; and

FIG. 6 shows the reaction of the technical system to said input signal in the form of the output signal.

The invention is based on the modeling of the nonlinear transfer behavior of a technical system, for example, a galvanic element or an electrolyzer. The transfer behavior is known to be the response (output signal y(t)) of the technical system to a specific excitation (input signal u(t)). In the case of a galvanic element, the input signal u(t) is, for example, an electric current l, and the output signal y(t) is a resulting electric voltage U, or vice versa. However, a technical system frequently has a (highly) nonlinear input/output behavior. Such nonlinear technical systems are frequently modeled by means of a known Volterra series, in the form Y(t)=y₁(t)+y₂(t)+ . . . yₙ(t) with the n-th nonlinear sub-dynamics

$${y}_{n} ( t ) = {\int }_{- ∞}^{∞} … {\int }_{- ∞}^{∞} {h}_{n} ( {τ}_{1} , … , {τ}_{n} ) u ( t - {τ}_{1} ) \cdot … \cdot u ( t - {τ}_{n} ) d {τ}_{1} … d {τ}_{n} .$$

Theoretically, n ranges from 1 to infinity; in practice, n<5 is sufficient for the vast majority of applications or technical systems. For example, n=3 suffices for a galvanic element. For a linear system (n=1), this results in the known convolution for linear, time-invariant systems

$$y ( t ) = {\int }_{- ∞}^{∞} h ( τ ) u ( t - τ ) d τ ,$$

with the impulse response h. The functions h₁, . . . , hₙ are the nonlinear impulse responses (in the time to domain) (h1 is the linear impulse response), which describe the nonlinear system and are called Volterra kernel.

The approach via a Volterra series has the advantage that the Volterra series can be easily transformed into the frequency range with the multidimensional Fourier transformation. The transfer behavior in the frequency range is given by the transfer functions Hₙ(jω) and results from the multidimensional Fourier transformation to

$${H}_{n} ( j {ω}_{1} , … , j {ω}_{n} ) = {\int }_{- ∞}^{∞} … {\int }_{- ∞}^{∞} {h}_{n} ( {τ}_{1} , … , {τ}_{n} ) {e}^{- j ( {ω}_{1} {τ}_{1} + … + {ω}_{n} {τ}_{n} )} d {τ}_{1} … d {τ}_{n} ,$$

which corresponds to the Volterra kernel of the n-th order in the frequency range. For n=1, hₙ is the linear impulse response and Hₙ is the linear transfer function and corresponds to the spectrum that is evaluated in the electrochemical impedance spectroscopy of a galvanic element as a technical system. With the Fourier transform of the input function U(jω), the output function y(t) becomes

$$y ( t ) = {\sum }_{n = 1}^{N} \frac{1}{{( 2 π )}^{n}} {\int }_{- ∞}^{∞} … {\int }_{- ∞}^{∞} {H}_{n} ( j {ω}_{1} , … , j {ω}_{n} ) {\prod }_{i = 1}^{n} U ( j {ω}_{i} ) {e}^{j ( {ω}_{1} + … + {ω}_{n} )} d {ω}_{1} … d {ω}_{n} .$$

### These

relationships are well known from the prior art, e.g., from chapter 6 of Billings, S.A., “Nonlinear System Identification: NARMAX methods in the time, frequency, and spatio-temporal domains,” Wiley Verlag, 2013, ISBN 978-1-119-94359-4, or Shan-Jen Cheng, et al., “Nonlinear modeling and identification of proton exchange membrane fuel cell (PEMFC),” Int. Journal of Hydrogen Energy 40 (2015), pages 9452-9461.

The advantage of a Volterra series is the direct interpretability of the Volterra kernels. With an exemplary input function u(t)=cos(ωₐt)+cos(ω_{b}t), for example, the Volterra kernel of the 2nd order (n=2) results from

$${y}_{2} ( t ) = {\sum }_{{ω}_{1 , 2} = [ \pm {ω}_{a} , \pm {ω}_{b} ]}^{allpermutations {ω}_{1 , 2}} H ( {ω}_{1} , {ω}_{2} ) {e}^{j ( {ω}_{1} + {ω}_{2} ) t} .$$

The frequency spectrum thus includes:

H(+ωₐ,+ωₐ)e^{j(ω}^{ₐ}^{+ω}^{ₐ}^{)t} as 2nd Harmonic frequency at (ωₐ+ωₐ)

H(+ωₐ,−ωₐ)e^{j(ω}^{ₐ}^{+ω}^{ₐ}^{)t} as constant amplification

H(+ωₐ,+ω_{b})e^{j(ω}^{ₐ}^{+ω}^{ₐ}^{)t} as intermodulation of the frequencies ωₐ, ω_{b}

H(+ωₐ,−ω_{b})e^{j(ω}^{ₐ}^{+ω}^{ₐ}^{)t} as intermodulation of the frequencies ωₐ, ω_{b},

etc.

For example, the Volterra kernel of the 2nd order can be represented as a contour plot for the amplification on a frequency plane ω₁, ω₂, which directly indicates the nonlinear to relationships between input and output. Basically, this is also known from the aforementioned chapter 6 of Billings, S.A., or from Shan-Jen Cheng, et al.

However, the problem with a Volterra series as a mathematical model for a given technical system (for example, a galvanic element) is that the Volterra kernels for the technical system are usually impossible or very difficult to determine directly or to identify from known data (for example, data measured on the technical system).

In order to remedy this problem, it has already been proposed to describe the nonlinear system in the time domain by means of parametric models which can subsequently be analytically transferred to the frequency range. A parametric model is a model that determines the current system output from the parameter-weighted past inputs and outputs.

The parametric model is present for identification and structure recognition in a “linear-in-the-parameters” form, wherein the past inputs and outputs, however, can be combined nonlinearly, e.g., in the form y(t)=θ₁*y(k−1)*y(k−2)+θ₁*u(k−1)*y(k−1)+ . . . , with the parameters θ. This has also been described in detail in the cited literature, for example, in chapters 2 and 3 of Billings, S.A., or Shan-Jen Cheng, and can therefore be assumed to be known. In the following, this known method shall nevertheless be described briefly for a better understanding.

The system is modeled with a polynomial NARMAX model, as an example of a parametric model, in the form

$$y ( k ) = {θ}_{0} + {\sum }_{{i}_{1} = 1}^{j} {θ}_{{i}_{1}} {x}_{{i}_{1}} ( k ) + {\sum }_{{i}_{1} = 1}^{j} {\sum }_{{i}_{2} = 1}^{j} {θ}_{{i}_{1} {i}_{2}} {x}_{{i}_{1}} ( k ) {x}_{{i}_{2}} ( k ) + … + {\sum }_{{i}_{1} = 1}^{j} … {\sum }_{{i}_{𝓁} = {i}_{𝓁 - 1}}^{j} {θ}_{{i}_{1} {i}_{2} … {i}_{𝓁}} {x}_{{i}_{1}} ( k ) {x}_{{i}_{2}} ( k ) … {x}_{{i}_{𝓁}} ( k ) + e ( k )$$

If the disturbances e(k) are omitted, it is also called a NARX model. With the model parameters θᵢ_{₁}ᵢ_{₂} _{. . . i}_{ₗ}, j=j_{y}+jᵤ+jₑ and

$${x}_{m} ( k ) = \{ \begin{matrix}y ( k - m ) & 1 \leq m \leq {j}_{y} \\ u ( k - ( m - {j}_{y} ) ) & {j}_{y} + 1 \leq m \leq {j}_{y} + {j}_{u} \\ e ( k - ( m - {j}_{y} - {j}_{u} ) ) & {j}_{y} + {j}_{u} + 1 \leq m \leq {j}_{y} + {j}_{u} + {j}_{e}\end{matrix} .$$

j denotes the number of the past outputs J_{y}, the number of the past input variables jᵤ, and the number of the past disturbance variables jₑ which are taken into account in the NARMAX model. j, or j_{y}, jᵤ, and jₑ, are parameterization options and can be selected. For a galvanic element as a technical system, for example, the selection of j_{y}=jᵤ=jₑ≤5 is sufficient.

In order to identify the parametric model, for example, the NARMAX model, for the technical system, N known data points are used. A data point is the output variable y(N) at a specific to input variable u(N), and, if applicable, at a disturbance variable e(N). A data point can be measured on the technical system, or it can be known. This representation is linear in the parameters θ and, as a result, the polynomial NARMAX or NARX model can be brought into the matrix form Y=Pθ[+e], with the output vector Y=[y(1), y(2), . . . , y(N)]^{T}, the parameter vector θ=[θ₁, θ₂, . . . , θₚ]^{T} possibly a disturbance vector e=[e(1), e(2), . . . , e(N)]^{T}, and the regressor matrix P which contains past output variables y(k−m) and past input variables u(k−(m−j_{y})). This linear equation system can be solved, for example, with the least-mean-square method: \hat{θ}=(P^{T}P)⁻¹P^{T}Y, resulting in the p parameters θ of the polynomial NARMAX model.

A better model quality can be achieved by breaking down the regressor matrix P into an orthogonal matrix W and a triangular matrix A using a known orthogonalization method, for example, the Gram-Schmidt orthogonalization method. The matrices W and A result from the orthogonalization method used.

Such transformation into orthogonal space is advantageous because a parametric model, such as the polynomial NARMAX or NARX model, can contain a very large number of potential parameters θ, many of which are not at all relevant for describing the input/output behavior of the technical system. A solution of this overdetermined equation system is frequently numerically difficult or even impossible because the regressor matrix P is very poorly conditioned. In addition to the calculation of the unknown parameters θ, the transformation, by contrast, also makes it possible to evaluate, which parameters θ are important and which parameters θ are not required (a so-called structure selection).

From this, a substitute problem can be formulated in the form

$$y = \underbrace{( {PA}^{- 1} )}_{w} \underbrace{( A θ )}_{g} [ + e ] = Wg [ + e ] .$$

Due to the transformation, the regressor matrix P forms an orthogonal basis, and the parameters gᵢ can be independently calculated with the above equation. The individual regressors (elements of the regressor matrix P) can be assessed with regard to significance with an error portion ERRᵢ of the form

$${ERR}_{i} = \frac{{g}_{i}^{2} 〈 {w}_{i} , {w}_{i} 〉}{〈 y , y 〉} \times 100 \% ,$$

wherein wᵢ are the columns of the matrix W and [symbol] ⋅,⋅ [symbol] is the inner vector product of two vectors. The individual regressors can thus be assessed according to importance, for example, in that only regressors are used which have a predetermined error portion ERRᵢ. Alternatively, the individual regressor candidates could be sorted by descending importance (as measured by the error portion ERRᵢ) and added in descending order, until a given total error ERR_{G} is reached, e.g., ERR=ΣᵢERRᵢ>ERR_{G} (e.g., 99.9%) is reached. The remaining regressors are set to zero. Subsequently, the substitute problem with the selected regressors can be solved in the orthogonal space. The solution follows, for example, in the form

$${g}_{i} = \frac{〈 y , {w}_{i} 〉}{〈 {w}_{i} , {w}_{i} 〉} .$$

Subsequently, the parameters gᵢ only have to be transformed back by solving the equation system Aθ=g. This is also known in principle, for example, from chapter 3.2 of Billings.

From the thus identified NARMAX or NARX model of the technical system, for example, the galvanic element, the Volterra kernels can be directly derived analytically. An example of this is the so-called recursive probing algorithm (frequently also referred to as harmonic probing algorithm) described in Chapter 6 of Billings. It is thus possible to utilize the fact that due to the Volterra series at a given harmonic input (regression functions), the basic answer of the technical system (harmonic, intermodulations, etc.) is known. Now, the model output y(t) of the Volterra series is equated with the parametric (NARMAX, NARX) model. For the terms of the parametric model (past outputs and inputs), these known regression functions are now substituted. The only remaining unknown in the equation system are the Volterra kernels, for which it is possible to solve, wherein the Volterra kernel of the n-th order depends on the Volterra kernel of the (n−1)-th order, etc. The Volterra kernels can be determined recursively therefrom.

This results in an analytic solution for the sought Volterra kernels Hₙ(jω₁, . . . , jωₙ) (also frequently referred to as Hₙ(ω₁, . . . , ωₙ) for simplicity) in the frequency range, i.e., the Volterra kernels can be represented as functions of the frequencies ωₙ. A Volterra kernel, as a complex function, thus has an amplification (amplitude) and a phase. Alternatively, a NARMAX or NARX model of the technical system could already be known, which can then be used to derive the Volterra kernels Hₙ(jω₁, . . . , jωₙ).

In order to determine the optimal excitation frequency (or frequencies) ωₘ according to the invention for diagnosing the technical system, the Volterra kernels H_{n,nom}(ω₁, ω₂, . . . ωₙ) of the n-th order with n>1, in particular the Volterra kernel of the 2nd order (n=2) H_{2,nom}(ω₁, ω₂), are initially identified for a fault-free operation of the technical system. In other words, a parametric model for a fault-free operating state is identified, as described above, and the Volterra kernels H_{n,nom}(ω₁, ω₂, . . . , ωₙ) of the n-th order are determined therefrom. The technical system is subsequently purposefully operated in a defined fault state, and the to Volterra kernels H_{n,fault}(ω₁, ω₂, . . . , ωₙ), in particular the Volterra kernel of the 2nd order (n=2) H_{2,fault}(ω₁, ω₂), are once again identified for the faulty operation of the technical system. According to the invention, the difference between the fault-free kernel H_{n,nom}, of the n-th order and the faulty kernel H_{n,fault} of the n-th order is now evaluated. For that purpose, an evaluation kernel H_{n,diff} of the n-th order as a function of fault-free kernel H_{n,nom} of the n-th order and the faulty kernel H_{n,fault} of the n-th order, i.e.,

H_{n,diff}(ω₁, ω₂, . . . , ωₙ)=f(H_{n,fault}(ω₁, ω₂, . . . , ωₙ),H_{n,nom}ω₁, ω₂, . . . , ωₙ)), is determined and evaluated. For example, an evaluation kernel H_{n,diff} of the n-th order can be determined as a quotient of the fault-free kernel H_{n,nom} of the n-th order and the faulty kernel H_{n,fault} of the n-th order

$${H}_{n , diff} ( {ω}_{1} , {ω}_{2} , … , {ω}_{n} ) = \frac{{H}_{n , fault} ( {ω}_{1} , {ω}_{2} , … , {ω}_{n} )}{{H}_{n , nom} ( {ω}_{1} , {ω}_{2} , … , {ω}_{n} )} ,$$

for example, the evaluation kernel of 2nd order

$${H}_{2 , diff} ( {ω}_{1} , {ω}_{2} ) = \frac{{H}_{2 , fault} ( {ω}_{1} , {ω}_{2} )}{{H}_{2 , nom} ( {ω}_{1} , {ω}_{2} )} .$$

The difference between the fault-free kernel H_{n,nom} of the n-th order and the faulty kernel H_{n,fault} of the n-th order H_{n,diff} (ω₁, ω₂, . . . , ωₙ)=|H_{n,fault}(ω₁, ω₂, . . . , ωₙ)−H_{n,nom}(ω₁, ω₂, . . . , ωₙ)|, for example, the evaluation kernel of the 2nd order H_{2,diff}(ω₁, ω₂)=|H_{2,fault}(ω₁, ω₂)−H_{2,nom}(ω₁, ω₂)|, could also be determined as the evaluation kernel H_{n,diff} of the n-th order. The quotient H_{n,fault}/H_{n,nom} describes the relative change in case of an error, and the difference H_{n,fault}−H_{n,nom} describes the absolute magnitude of the change. The two variables can be evaluated both individually and in combination.

The evaluation kernel H_{n,diff} can now be evaluated such that those frequency ranges are sought, in which an amplification of the evaluation kernel H_{n,diff}, which exceeds a defined limit amplification, is present. Preferably, the frequency is sought, where the maximum amplification occurs. The difference kernel of the 2nd order is particularly advantageous because it can still be represented simply graphically as a 3D plot or as a contour plot of the amplification, which simplifies the evaluation. This shall be explained with FIGS. 1 to 3 using the example of a Volterra kernel of the 2nd order and the quotient as evaluation kernel H_{2,diff}.

FIG. 1 shows the amplification of the Volterra kernel of the 2nd order H_{2,nom} of a technical system, for example, a galvanic element, in the fault-free state. FIG. 2 shows the amplification of the Volterra kernel of the 2nd order H_{2,fault} of the same technical system in the faulty state, i.e., in a concrete, clear case of error. In each case, the Volterra kernel of the 2nd order H_{2,nom}, H_{2,fault} is shown as a two-dimensional contour plot of the amplification as a function of the frequencies ω₁, ω₂, which are plotted in the drawings, as is frequently common in this context, as a frequency normalized with half the sampling frequency. Since the Volterra kernels are complex functions, the amplification (as the absolute value of the complex function, i.e., of the Volterra kernel) and the phase can each be calculated and depicted as a function of the frequencies (ω₁, ω₂, . . . , ωₙ) for a Volterra kernel.

FIG. 3 shows the evaluation kernel

$${H}_{2 , diff} ( {ω}_{1} , {ω}_{2} ) = \frac{{H}_{2 , fault} ( {ω}_{1} , {ω}_{2} )}{{H}_{2 , nom} ( {ω}_{1} , {ω}_{2} )}$$

of the Volterra kernel of the 2nd order of the technical system. The largest amplification of the evaluation kernel (again as absolute value of the complex evaluation kernel) can be expected at the occurring harmonic frequencies, i.e., at ω₁=ω₂, which is represented by a diagonal in the evaluation kernel H_{diff}. However, the greatest amplification does not have to necessarily occur at the harmonic frequencies but can also occur, for example, at intermodulations. In the depicted example, the largest amplification occurs in the range of ∫₁=ω₂=[0.01, 0.02]. If the excitation frequency ωₘ of the technical system is thus selected in this range, a good excitation of the underlying fault state that caused the faulty Volterra kernel H_{2,fault} can be expected. This evaluation is most easily performed manually, but can of course also be automated by maximum value searches (also as range searches).

This shows that optimal excitation frequencies ωₘ of the technical system can be determined for different fault states.

If the input signal u(t) of the underlying technical system in normal operation is subsequently superimposed by an excitation signal a(t) with an excitation frequency ωₘ thus determined, a best possible excitation of the output signal y(t), which is characteristic for the fault state, can be expected in case of an error.

If the Volterra kernels of the 2nd order are used to determine the excitation frequencies, two excitation frequencies (ωₘ₁, ωₘ₂) result, which, for example, could be introduced with an excitation signal a(t)=A₁ cos(ωₘ₁t)+A₂ cos(ωₘ₂t). If ωₘ₁=ωₘ₂=ωₘ, then a(t)=A cos(ωₘt), for example, can also be used as the excitation signal.

When compared to the amplitudes of the input signal, the excitation signal a(t) is of a low amplitude (e.g., A, A₁, A₂ less than 10%, preferably less than 5%, of the expected maximum amplitude of the input signal) in order to not disturb the normal operation of the technical system. The ongoing diagnosis of the operation of the technical system can then be carried out, for example, in a known manner continuously with electrochemical impedance spectroscopy or the total harmonic distortion analysis.

Of course, with the excitation signal a(t), it is possible in this manner to also excite different fault states simultaneously by means of different further excitation frequencies ωₘ. The different fault states can subsequently be determined in the frequency spectrum of the output to variable, depending on the frequency range of the frequency spectrum, in which a reaction is detected.

If several excitation frequencies ωₘₚ, p≥1, are contained in the excitation signal a(t), it is important that the excitation frequencies ωₘₚ do not influence each other in the frequency spectrum, which can be easily ensured by a suitable selection. It is therefore important to ensure a clean separation of the resulting frequency spectra in order to be able to clearly distinguish the different fault states.

With the identification of the Volterra kernel, a nonlinear, accurate time model (polynomial NARMAX or NARX model) is also obtained quasi as a “by-product” of the method according to the invention. This provides options for a wealth of further diagnostic options based on the time model, which are known under the collective term model-based fault diagnosis and isolation (FDI). The identified time model can be continuously determined and updated during the online operation of the technical system.

The parametric model of the technical system, e.g., a NARMAX or NARX model, can be present or can be identified in advance, as shall be described below using a galvanic element as a technical system 1. The exemplary technical system in the form of the galvanic element is shown in FIG. 4.

Electrical loads 2a, 2b, such as a hybrid powertrain or a vehicle battery, are connected to the galvanic element in the form of a fuel cell. Between the fuel cell and the loads 2a, 2b, a power unit 3 can also be arranged in a known manner in order to control the energy flow, and the voltage and current levels. Particularly in case of a fuel cell, the galvanic element can also be connected to an unspecified, well-known gas conditioning 4 which is used to condition the reaction gases for the fuel cell as needed, in particular with regard to pressure, humidity, temperature, mass flow. A gas source 5, e.g., for hydrogen, can also be provided. The gas conditioning is shown schematically and shall not be described in detail. Faults in the gas conditioning can lead to faulty operating states in the galvanic element. For example, a reaction gas can be too wet or too dry, the pressure of a reaction gas can be too high, the mass flow of a reaction gas can be too low, etc. Similarly, damage, such as a damaged ion exchange membrane of a cell, or changes can occur in the galvanic element, which can be recognized as fault states. Such fault states lead to a suboptimal operation of the galvanic element and can even result in damage or the destruction of the galvanic element. It is therefore important to continuously monitor the operating state of the galvanic element in order to be able to quickly take appropriate countermeasures in case of a fault. The monitoring is supposed to take place using the current and voltage curve of the galvanic element, i.e., the input and output variables of the technical system 1.

The galvanic element is now guided to a fault-free operating state, i.e., for example, the gas to conditioning operates flawlessly, and all the reaction gases are sufficiently and properly conditioned, and no other fault state is present. In this state, an input signal u(t), herein, e.g., in the form of a temporal current curve l(t), is impressed onto the galvanic element, said input signal being supposed to excite the galvanic element in the best possible manner in order to capture the static and dynamic behavior of the galvanic element in the best possible manner. A suitable input signal u(t) is, for example, a current curve l(t) in the form of an amplitude-modulated pseudo-random binary sequence (APRBS) signal, as shown in FIG. 5, or a random Gaussian sequence signal. The resulting output signal y(t), e.g., in the form of the temporal voltage curve U(t), is shown in FIG. 6 for a short time interval. The input signal u(t) and the output signal y(t) are sampled at a predetermined sample rate, e.g., 100 Hz, resulting in the data points and from which, as outlined above, a NARMAX or NARX model is identified. The identified NARX model results, for example, in the form

$$y ( k ) = - 0.4453 u ( k - 2 ) + 0.0059 y ( k - 4 ) + 1.2348 y ( k - 1 ) + 0.5177 u ( k - 3 ) ++ 0.0015 y ( k - 1 ) u ( k - 2 ) - 0.0018 y ( k - 1 ) u ( k - 3 ) - 0.0004 u ( k - 2 ) u ( k - 2 ) -- 0.0323 y ( k - 2 ) - 0.0121 y ( k - 5 ) + 0.0407 + 0.0003 u ( k - 2 ) u ( k - 3 ) -- 0.0005 y ( k - 1 ) y ( k - 1 ) - 0.2171 y ( k - 3 ) + 0.0003 y ( k - 1 ) y ( k - 3 ) -- 0.087 u ( k - 5 ) + 0.0004 y ( k - 3 ) u ( k - 5 ) - 0.0002 y ( k - 3 ) u ( k - 3 ) .$$

As outlined above, this parametric model can subsequently be analytically transformed into the frequency range, resulting in the Volterra kernels in the frequency range. This is repeated, wherein the galvanic element is now operated in a defined fault state, for example, with a too low relative humidity of a process gas. From the evaluation kernel, the at least one excitation frequency ωₘ is then identified, with which the technical system 1 must be excited in order to optimally excite this fault state during operation of the technical system 1, thus making it diagnosable.

1. Method for diagnosing a technical system which maps an input signal (u(t)) onto an output signal (y(t)), the method comprising the steps of:
during operation of the technical system, the input signal (u(t)) is superimposed by an excitation signal (a(t)) with at least one excitation frequency (ωₘ);
for diagnosing, at least one of the input signal (u(t)) and the output signal (y(t)) is analyzed to detect a fault state of the technical system, characterized in that the technical system is modelled as a Volterra series with Volterra kernel (Hₙ(ω₁, . . . , ωₙ)), that,
in a fault-free state of the technical system, a Volterra kernel (H_{n,nom}(ω₁, . . . , ωₙ)) of the n-th order is determined for the fault-free state, and
for a defined fault state of the technical system, a Volterra kernel (H_{n,fault}(ω₁, . . . , ωₙ)) of the n-th order is determined for the fault state;
determining an evaluation kernel (H_{n,fault}(ω₁, . . . , ωₙ)) of the n-th order as a function of the Volterra kernel (H_{n,nom}(ω₁, . . . , ωₙ)) of the n-th order for the fault-free state and of the Volterra kernel (H_{n,fault}(ω₁, . . . , ωₙ)) of the n-th order for the fault state;
evaluating the evaluation kernel (H_{n,diff}(ω₁, . . . , ωₙ)) of the n-th order to determine a frequency range, in which an amplification of the evaluation kernel (H_{n,fault} (ω₁, . . . , ωₙ)) exceeds a predefined limit value; and
selecting the at least one excitation frequency (ωₘ) for the excitation signal (a(t)) from the determined frequency range.

2. The method according to claim 1, wherein the step of determining the evaluation kernel further includes
determining a quotient of the Volterra kernel (H_{n,nom}(ω₁, . . . , ωₙ)) of the n-th order for the fault-free state and of the Volterra kernel (H_{n,fault}(ω₁, . . . , ωₙ)) of the n-th order for the fault state.

3. The method according to claim 1, wherein the step of determining the evaluation kernel further includes
determining the difference between the Volterra kernel (H_{n,nom}(ω₁, . . . , ωₙ)) of the n-th order for the fault-free state and the Volterra kernel (H_{n,fault}(ω₁, . . . , ωₙ)) of the n-th order for the fault state.

4. The method according to claim 1, wherein the at least one excitation frequency (ωₘ) for the excitation signal (a(t)) is selected, in which an amplification of the evaluation kernel (H_{n,diff}(ω₁, . . . , ωₙ)) of the n-th order has a maximum value.

5. The method according to claim 1, wherein the technical system is described in the time domain by means of a parametric model from which the Volterra kernels (Hₙ(ω₁, . . . , ωₙ)) are derived analytically.

6. The method according to claim 5, wherein the Volterra kernels (Hₙ(ω₁, . . . , ωₙ)) are derived from the parametric model with a harmonic probing algorithm.

7. The method according to claim 5, wherein the parametric model is a polynomial NARMAX or NARX model.

8. The method according to claim 2, wherein the technical system is described in the time domain by means of a parametric model from which the Volterra kernels (Hₙ(ω₁, . . . , ωₙ)) are derived analytically.

9. The method according to claim 8, wherein the parametric model is a polynomial NARMAX or NARX model.

10. The method according to claim 8, wherein the Volterra kernels (Hₙ(ω₁, . . . , ωₙ)) are derived from the parametric model with a harmonic probing algorithm.

11. The method according to claim 3, wherein the technical system is described in the time domain by means of a parametric model from which the Volterra kernels (Hₙ(ω₁, . . . , ωₙ)) are derived analytically.

12. The method according to claim 11, wherein the parametric model is a polynomial NARMAX or NARX model.

13. The method according to claim 11, wherein the Volterra kernels (Hₙ(ω₁, . . . , ωₙ)) are derived from the parametric model with a harmonic probing algorithm.

14. The method according to claim 4, wherein the technical system is described in the time domain by means of a parametric model from which the Volterra kernels (Hₙ(ω₁, . . . , ωₙ)) are derived analytically.

15. The method according to claim 14, wherein the parametric model is a polynomial NARMAX or NARX model.

16. The method according to claim 14, wherein the Volterra kernels (Hₙ(ω₁, . . . , ωₙ)) are derived from the parametric model with a harmonic probing algorithm.
